(19) United States
(12) Patent Application Publication
(10) Pub. No.: US 2006/0281237 A1
(43) Pub. Date: Dec. 14, 2006

(54) METHOD OF MANUFACTURING JUNCTION FIELD EFFECT TRANSISTOR

(75) Inventors: Akiyoshi Kudo, Toyama (JP); Yoshiharu Anda, Toyama (JP); Akiyoshi Tamura, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/382,991

(22) Filed: May 12, 2006

(30) Foreign Application Priority Data
Jun. 9, 2005 (JP) 2005/169023

(51) Int. Cl. H01L 21/338

(52) U.S. Cl. 438/172

(57) ABSTRACT

A method of manufacturing a junction field-effect transistor which controls variations of p-type impurities in a gate region and obtains a favorable PN junction characteristic includes: depositing ZnO in a thin layer by a sputtering method on a surface of a region in which a gate electrode of an n⁺-AlGaAs layer formed on a GaAs substrate is to be formed; forming a p-type gate region by solid-phase diffusion which is performed by processes of rapid heating and fast cooling; removing the ZnO with wet etching using tartaric acid and the like so as to expose the p-type gate region; and forming the gate electrode on the exposed p-type gate region.

### BACKGROUND OF THE INVENTION

(1) Field of the Invention

The present invention relates to a method of manufacturing a junction field-effect transistor (referred to simply as Junction FET or JFET), and particularly to a method of forming a p-type gate region using a solid-phase diffusion method.

(2) Description of the Related Art

The field-effect transistor, which uses a compound semiconductor as typified by GaAs, has widely been in practical use as a semiconductor device for a portable terminal in mobile communications. A 3FET which forms a PN junction in a junction of a gate electrode is an FET which performs a current control by controlling a depletion layer of the PN junction, and which can offer superior device performance as compared to a Schottky junction field-effect transistor. Thus, it is becoming commonly used as a high-frequency device of a cell phone at present.

Methods for forming a p-type region on the gate electrode junction of the JFET include, for example: a vapor phase diffusion method which uses, as a vapor-phase diffusion source, gas including Zn which is a p-type impurity such as Zn(C₂H₅)₂; or a solid-phase diffusion method using a Zn thin film.

As a method of manufacturing a JFET, for example, Japanese Laid-Open Patent Application No. S58-143582 Publication describes a method with which a favorable PN junction characteristic is obtained by doping Zn into a gate electrode which is made of Pt and then diffusing the Zn, simultaneously with an alloying process, into an n-type GaAs from a junction between a gate metal and a semiconductor. It also discloses a method of manufacturing a JFET with a simple process and with excellent reproducibility.

As an example of a method for forming a p-type region by solid-phase diffusion, FIGS. 1A and 1 B show a method of manufacturing a IFET with the conventional technology.

FIG. 1A shows a simplified epitaxial layer in the case where an n-type channel layer 12 is laminated on a GaAs substrate 1, and a gate electrode 10 is formed using metals such as Pt doped with Zn. Then, as shown in FIG. 1B, solid-phase diffusion is performed, by thermal processing, between the gate electrode 10 doped with Zn and the n-type channel layer 12 so that a p-type gate region 8 is formed. Moreover, 11 in FIGS. IA and 1B shows an n⁺-GaAs cap layer.

However, with the aforementioned method of the conventional technology, as the junction between the gate metal and the semiconductor and the p-type gate region are simultaneously formed with an alloying process by doping Zn into the gate electrode, it is difficult to form the desired p-type gate region with superior performance as well as to obtain a favorable PN junction characteristic with superior uniformity.

In addition, it is difficult to obtain a shallow and highly concentrated doping profile, and to provide a JFET with high process yields.

### SUMMARY OF THE INVENTION

The object of the present invention is to provide a method of manufacturing a IFET that can control, with an easy process, variations of impurities in the gate region and can obtain a favorable PN junction characteristic, in order to solve the aforementioned conventional problems.

To achieve the aforementioned object, the present invention is concerning a method of manufacturing a JFET, made by forming a gate electrode in a p-type impurity region formed on a semiconductor substrate, which includes: depositing ZnO in a thin layer on a surface of a region in which the p-type impurity region of the semiconductor substrate is to be formed; forming the p-type impurity region by solid-phase diffusion; removing the ZnO so as to expose the p-type impurity region; and forming a gate electrode on the exposed p-type impurity region.

According to the method of manufacturing the 3FET in the present invention, it is possible to realize a high-uniform characteristic of a threshold voltage, compared with the conventional method of solid-phase diffusion. In addition, as compared to the conventional case where impurities are doped into a gate electrode by solid-phase diffusion, it is possible to provide a JFET with high performance and a high process yield, such as that where a p-type gate region with high uniformity and a PN junction with high uniformity are compatible.

### FURTHER INFORMATION ABOUT TECHNICAL BACKGROUND TO THIS APPLICATION

The disclosure of Japanese Patent Application No. 2005-169023 filed on Jun. 9, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIGS. 1A and 1B are cross-section diagrams showing an example of a manufacturing process of a conventional semiconductor device.

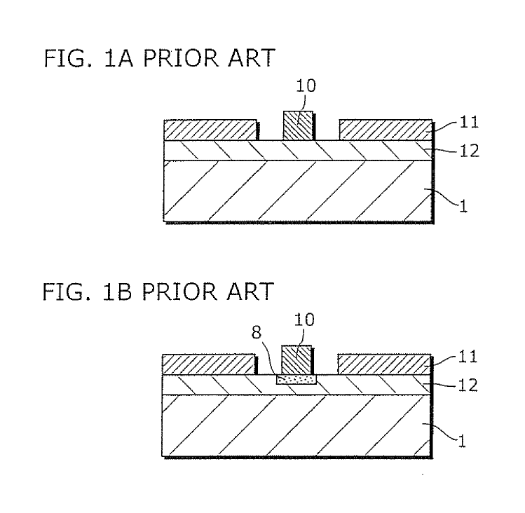

FIGS. 2A to 2E are cross-section diagrams showing an example of a manufacturing process of a semiconductor device in the embodiment of the present invention.

### DESCRIPTION OF THE PREFERRED EMBODIMENT

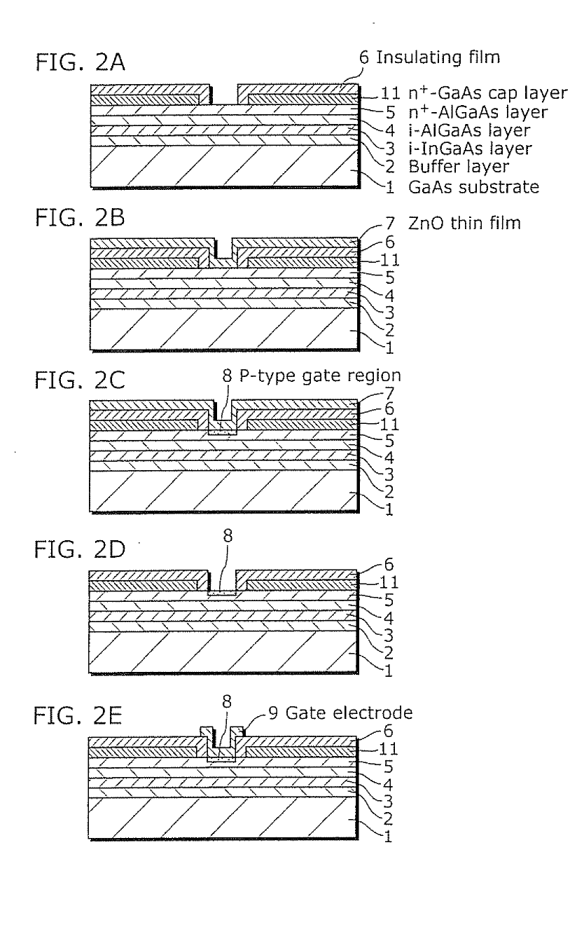

The embodiment of the present invention is specifically described hereinafter with reference to FIGS. 2A to 2E.

FIGS. 2A to 2E are cross section diagrams showing an example of a manufacturing process of a semiconductor device in the embodiment of the present invention.

FIG. 2A shows a simplified cross section with an epitaxial structure of the semiconductor manufacturing device according to the present embodiment, and is an example using an epitaxial substrate which laminates, on the GaAs substrate 1: a buffer layer 2 made up of a laminated structure of i-GaAs and i-AlGaAs; an i-InGaAs layer 3; an i-AlGaAs layer 4; an n⁺-AlGaAs layer 5 and an n⁺-GaAs cap layer 11.

In addition, FIG. 2A shows the state which is obtained by the following processes. An insulating film 6 (for example silicon nitride, oxide nitride) which is used as a mask to form a gate electrode is deposited by a plasma CVD method and the like. Then, an opening is formed in the insulating film 6 on the n⁺-AlGaAs layer 5 where the gate electrode is in contact, in order to ensure the width for obtaining the desired gate length This opening is made by performing dry etching with a resist mask (not illustrated), such as a high frequency induction coupling plasma etching method using gases such as CHF₃ or SF₆. Finally, a resist pattern used for the mask is removed.

FIG. 2B is the state in which a ZnO thin film 7 having the desired film thickness is formed on the insulating film 6 and on the n⁺-AlGaAs layer 5 at the opening by a sputtering method.

The ZnO thin film 7 is formed in an overall thin film by the sputtering method with high uniformity, and even in a large area compound substrate, such as a 6-inch GaAs substrate, it is possible to form the film with high uniformity. Even in the gate opening part which is opened to ensure the width for obtaining the desired gate length, the homogeneous ZnO thin film 7 is deposited.

In addition, in diffusing impurities by thermal processing on the substrate, phosphorus may be doped into the ZnO thin film 7 for the purpose of preventing arsenic from being dissociated from the n⁺-AlGaAs layer 5.

The state shown in FIG. 2C is that the p-type gate region 8 is formed by performing Zn solid-phase diffusion in which Zn is used as a p-type impurity in the ZnO thin film 7 and rapid heating and fast cooling processes, such as lamp annealing at a temperature of 600 degrees Celsius for 15 second, are performed.

By using the ZnO thin film 7 with high uniformity as a solid-phase diffusion source, it is possible to form, with high uniformity, the shallow and highly concentrated p-type gate region even on a large area compound substrate, such as a 6-inch substrate, and to realize a high-uniform characteristic of a threshold voltage for a FET. As thermal processing conditions of Zn solid-phase diffusion, a heating temperature ranging from 600 to 800 degrees Celsius and heating time ranging from 15 to 120 seconds are appropriate.

The state shown in FIG. 2D is that the ZnO thin film 7 is removed from the overall substrate by a wet etching method, and that the p-type gate region 8 is exposed. The wet etching can completely remove the ZnO thin film 7 which is a solid-phase diffusion source without affecting the n⁺-AlGaAs layer 5 and insulating film 6, for example, by using tartaric acid. The semiconductor manufacturing process of the p-type gate region 8 formed on the surface of the n⁺-AlGaAs layer 5 becomes more stable by removing the unnecessary ZnO thin film 7. This indicates that as compared to the conventional example, in which Zn, which is a diffusion source, is doped into the gate electrode metal, much improvement on the process controllability becomes possible in the present embodiment.

FIG. 2E shows the state in which the gate electrode 9 is formed on the gate opening part. Metals such as WSi or Ti/Pt/Au are deposited on the overall surface by the sputtering method or evaporation method. Using the tartaric acid as mentioned earlier, it is possible to form a favorable gate electrode by contacting the metal with the n⁺-AlGaAs layer 5 from which the ZnO thin film 7, which is a solid-phase diffusion source, has completely been removed.

Then, in order to obtain the desired upper width of the gate electrode in the center of the gate opening part, resist patterning (not illustrated) is performed, and the gate electrode 9 is formed by dry etching methods, such as the high frequency induction coupling plasma etching, or other methods, such as ion milling. By removing the unnecessary resist (not illustrated) which has been used for the mask, using the methods such as oxygen ashing, a cross-sectional shape shown in FIG. 2E is obtained. In addition, an ohmic electrode (not illustrated) is formed by performing ohmic alloying processing with metals such as Au/Ge/Ni on the n⁺-GaAs cap layer 11 arranged on both sides of the gate electrode 9.

Following the aforementioned manufacturing processes, the JFET of the present embodiment is completed.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention can be applied not only to the case where Zn is diffused on an n⁺-AlGaAs layer but also to an AlGaAs layer, GaAs layer, and InGaP layer which are non-doped or low n⁻ doped, and in addition, it can also be applied to a field-effect transistor (FET) with GaAlAs/InGaAs, GaInP, and InP material systems.

What is claimed is:

1. A method of manufacturing a junction field-effect transistor,
wherein said junction field-effect transistor includes a gate electrode that is formed on a p-type impurity region formed on a semiconductor substrate,
said method comprising:
depositing ZnO in a thin layer on a surface of a region in which the p-type impurity region of the semiconductor substrate is to be formed;
forming the p-type impurity region by solid-phase diffusion;
removing the ZnO so as to expose the p-type impurity region; and
forming the gate electrode on the exposed p-type impurity region.

2. The method of manufacturing the junction field-effect transistor according to claim 1,
wherein the deposited ZnO includes phosphorus.

3. The method of manufacturing the junction field-effect transistor according to claim 1,
wherein the solid-phase diffusion is performed by processes of rapid heating at a heating temperature ranging from 600 to 800 degrees Celsius for heating time ranging from 15 to 120 seconds, and fast cooling.

4. The method of manufacturing the junction field-effect transistor according to claim 1,
wherein said removing of the ZnO includes wet etching with tartaric acid.
